(19) United States
(12) Patent Application Publication
(10) Pub. No.: US 2016/0304815 A1
(43) Pub. Date: Oct. 20, 2016

(54) METHODS AND CHEMICAL SOLUTIONS FOR CLEANING PHOTOMASKS USING QUATERNARY AMMONIUM HYDROXIDES

(71) Applicants: Intermolecular, Inc., San Jose, CA (US); Samsung Electronics Co., Ltd., Gyeonggi-do (KR)

(72) Inventors: Jeffrey Lowe, Cupertino, CA (US); Kim Van Berkel, San Jose, CA (US); Jae-Hyuck Choi, Gyeonggi-Do (KR)

(73) Assignees: Intermolecular, Inc., San Jose, CA (US); Samsung Electronics Co., Ltd., Gyeonggi-do (KR)

(21) Appl. No.: 15/132,480

(22) Filed: Apr. 19, 2016

Related U.S. Application Data
(60) Provisional application No. 62/149,847, filed on Apr. 20, 2015.

(51) Int. Cl. C11D 3/30; B08B 3/10; C11D 3/28; B08B 3/08; G03F 1/82; G03F 1/22

(52) U.S. Cl. CPC C11D 3/30; G03F 1/82; G03F 1/22; C11D 3/28; B08B 3/08; B08B 3/10

(57) ABSTRACT

Embodiments provided herein describe methods and chemical solutions for cleaning photomasks. A photomask is provided. The photomask is exposed to a chemical solution. The chemical solution includes a quaternary ammonium hydroxide.

The quaternary ammonium hydroxide may include at least one of tetraethyl ammonium hydroxide (TEAH), tetrapropyl ammonium hydroxide (TPAH), or a combination thereof. The photomask may be an extreme ultraviolet (EUV) lithography photomask.

### CROSS-REFERENCE TO RELATED APPLICATIONS

This application claims priority to U.S. Provisional Application No. 62/149,847, filed on Apr. 20, 2015, which is herein incorporated by reference for all purposes.

### TECHNICAL FIELD

The present invention relates to cleaning photomasks used in photolithography processes. More particularly, this invention relates to methods for cleaning photomasks using quaternary ammonium hydroxides and the chemical solutions used in such methods.

### BACKGROUND

Photolithography, also known as simply “lithography,” is commonly used in the formation of microelectronic devices (e.g., semiconductor devices) and other structures on wafers or other substrates. In general, a surface is coated with a resist (or photoresist), and light is projected onto the resist through a mask, or reflected by the mask onto the surface. Depending on the type of resist used, the light causes alterations in the chemical structures of the resist, which upon the application of a developer either allows the exposed portions of the resist to be removed or prevents the exposed portions of the resist from being removed. Once a portion of the resist is removed, the exposed substrate surfaces may be etched or otherwise processed.

In recent years, extreme ultraviolet (EUV) lithography has become increasingly used due to some of the limitations associated with conventional (e.g., optical) lithography. EUV lithography often utilizes electromagnetic radiation having a wavelength of between, for example, 10 nanometers (nm) to 124 nm, which interacts with various optics, such as condensers, lenses, and mirrors, and is projected onto a photomask (or mask) and reflected onto the coated surface of the substrate. The process is often performed in a controlled atmosphere environment (e.g., a vacuum)

During the process, various materials, such as organic compounds, may be liberated from the resist, or unintentionally brought into the process chamber as contaminants, and deposited onto various components in the system including the photomask, in the form of, for example, carbon residue. This residue, or other particles and foreign material, may cause defects in the optics and mask that may negatively affect the performance of the process.

EUV photomasks are relatively complicated and expensive to manufacture. Thus, it is desirable to be able to reuse the masks as much as possible before they are replaced with new masks. In order to maintain suitable performance, the masks must be intermittently cleaned to remove the carbon residue and any other particles or foreign material. Conventional cleaning methods typically involve the use of a sulfuric acid/hydrogen peroxide mixture (SPM), perhaps in combination with mechanical processes (e.g., brushing) and/or ultrasonic energy. The SPM-type chemistries are highly oxidative and tend to damage the masks, in particular, the ruthenium capping layer, and affect the critical dimensions of the masks, thus shortening their service life.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a simplified cross-sectional view of a photomask according to some embodiments.

FIG. 2 is a simplified cross-sectional view of the photomask of FIG. 1 with carbon residue deposited thereon.

FIGS. 3-36 are images depicting the effectiveness of chemical solutions described herein at removing carbon residue from photomasks.

FIG. 37 is block diagram of a method according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims, and numerous alternatives, modifications, and equivalents are encompassed.

Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide methods for cleaning photomasks (or masks) used in photolithography, such as extreme ultraviolet (EUV) lithography, and the chemical solutions used in such methods. In some embodiments, the chemical solutions include one or more quaternary ammonium hydroxide. The quaternary ammonium hydroxide(s) includes, for example, tetraethyl ammonium hydroxide (TEAH), tetrapropyl ammonium hydroxide (TPAH), or a combination thereof.

In some embodiments, the chemical solutions also include a surfactant. The surfactant may include t-octylphenoxypolyethoxyethanol, trimethylnonylpolyethylene glycol, or a combination thereof. In some embodiments, the chemical solutions also include diethylenetriamine (DETA), n-methyl-2-pyrrolidone (NMP), or a combination thereof (e.g., as a corrosion inhibitor).

Experimental data shows that these chemical solutions are effective at removing carbon residue. Additionally, the non-oxidative chemistry of the solutions does not cause the damage to the masks associated with conventional SPM chemistries, such as damage to the ruthenium layer with respect to the thickness, roughness, and extreme ultraviolet reflectance (EUVR) and damage to the absorber layer causing changes in critical dimensions. As a result, the service life of the masks are extended.

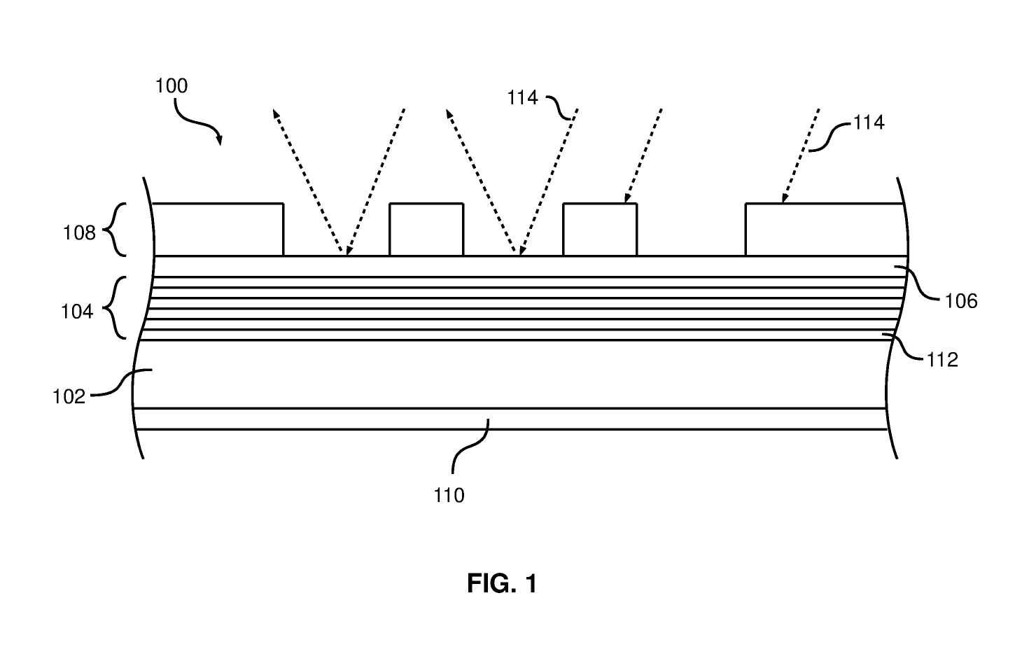

FIG. 1 is a simplified illustrates an EUV lithography photomask 100 according to some embodiments. The photomask 100 includes a substrate 102, a multi-layer stack 104, a capping layer 106, an absorber layer 108, and a backing layer 110. In some embodiments, the substrate 102 is made of a material with a relatively low coefficient of thermal expansion, such as glass (e.g., titanium-doped silica), and has a thickness of, for example, between about 5 millimeters (mm) and 8 mm.

In some embodiments, the multi-layer stack 104 is formed on a side of the substrate 102 opposite the backing layer 110. The multi-layer stack 104 may include a series of alternating layers of molybdenum and silicon, with each of the individual layers having a thickness of, for example, between about 2 nanometers (nm) and 5 nm (e.g., about 3 nm thick molybdenum layers and about 4 nm thick silicon layers). Although only six layers are shown in the multi-layer stack in FIG. 1, it should be understood that dozens of such layers may be used. For example, the multi-layer stack 104 may include 40-50 pairs of molybdenum and silicon layers, for a total of 80-100 individual layers. In some embodiments, the pairs of layers are arranged such that a molybdenum layer within the multi-layer stack 104 is formed directly on the substrate 102, and the capping layer 106 is formed directly on a silicon layer within the multi-layer stack 104. In some embodiments, ruthenium layers are used in the multi-layer stack in place of the molybdenum layers.

Still referring to FIG. 1, the capping layer 106 is formed above the multi-layer stack 104. In some embodiments, the capping layer 106 includes (e.g., is made of) ruthenium and has a thickness of, for example, between about 2 nm and about 5 nm, such as about 4 nm. In some embodiments, the capping layer 106 includes silicon, perhaps in combination with ruthenium.

The absorber layer 108 is formed above the capping layer 106. In some embodiments, the absorber layer 108 includes (e.g., is made of) tantalum, tantalum nitride, tantalum nitride oxide, tantalum-boron oxide, tantalum-boron nitride, or a combination thereof and may have a thickness of, for example, between about 50 nm and about 75 nm. As is shown in FIG. 1, the absorber layer 108 is patterned to selectively expose portions of the capping layer 106 and/or portions of the multi-layer stack 104 below the exposed portions of the capping layer 106.

The backing layer 110 is formed on the side of the substrate 102 opposite the multi-layer stack 104. The backing layer 110 may be made of a conductive material to allow for electrostatic chucking of the photomask 100 during the photolithography process. In some embodiments, the backing layer 110 is made of chromium nitride and may have a thickness of, for example, between about 70 nm and about 100 nm.

Still referring to FIG. 1, during the photolithography process, electromagnetic radiation 114 is projected (or propagated) onto the side of the photomask 100 having the multi-layer stack 104, the capping layer 106, and the absorber layer 108. In some embodiments, the electromagnetic radiation is in the ultraviolet range of the electromagnetic spectrum and has a wavelength (or wavelengths) between about 10 nm and about 124 nm. In some embodiments, the electromagnetic radiation is formed by creating a plasma with xenon gas, from which electrons are liberated and light is radiated at wavelengths of about 13-14 nanometers.

As shown in FIG. 1, the electromagnetic radiation 114 that is directed onto the absorber layer 108 is not reflected (and/or is absorbed) by the absorber layer 108, while the electromagnetic radiation 114 that is directed onto the exposed portions of the capping layer 106 is reflected by the capping layer 106 and/or the multi-layer stack 104, as a result of, for example, constructive interference caused by the various layers within the photomask 100 (e.g., the capping layer 106 and/or the multi-layer stack 104). As a result, a selected pattern of electromagnetic radiation is reflected by the photomask 100 onto a substrate (not shown) coated with resist (or photoresist), thereby selectively exposing a pattern of the photoresist to the electromagnetic radiation.

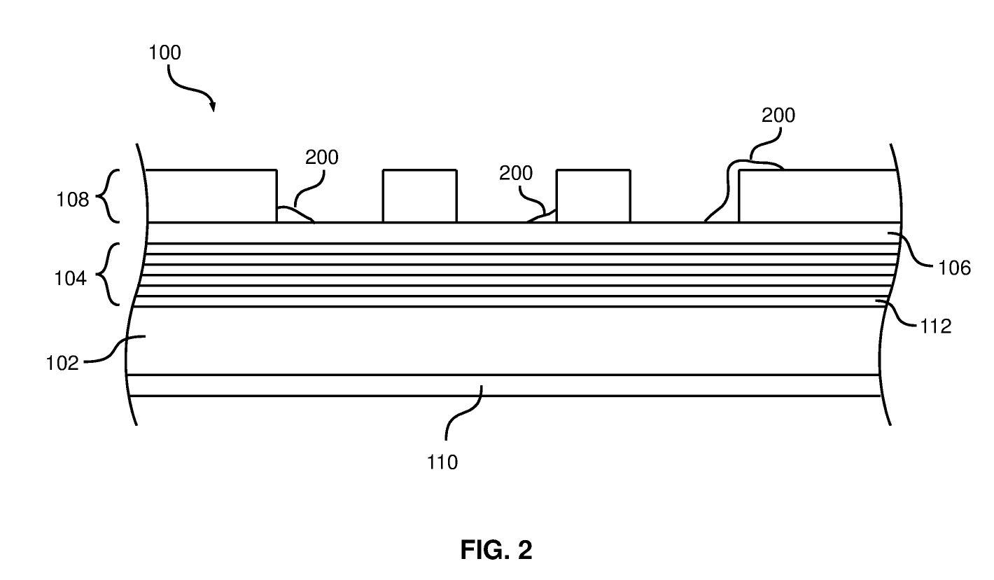

Referring now to FIG. 2, during the photolithography process, residue, such as carbon residue (or other particles or foreign material) 200, may be deposited or build up on various portions of the photomask 100, such as the capping layer 106 and/or the absorber layer 108. As described above, the carbon residue is typically removed from the photomask 100 in a process that utilizes a sulfuric acid/hydrogen peroxide mixture (SPM), perhaps in combination with mechanical processes (e.g., brushing) and/or ultrasonic energy. The SPM-type chemistries are highly oxidative and tend to damage the masks, in particular, the ruthenium capping layer and the absorber layer, thus reducing the service life of the mask.

In some embodiments described herein, the carbon residue is at least partially removed using by exposing the photomask 100 to a chemical (or cleaning) solution that includes at least one quaternary ammonium hydroxide. In some embodiments, the quaternary ammonium hydroxide includes tetraethyl ammonium hydroxide (TEAH), tetrapropyl ammonium hydroxide (TPAH), or a combination thereof. It should be understood that in at least some embodiments the chemical solutions include water (e.g., deionized water) in addition to the various components described. Thus, in some embodiments, the chemical solution includes (e.g., comprises) at least one quaternary ammonium hydroxide and water.

In some embodiments, the chemical solutions also include a surfactant. The surfactant may include t-octylphenoxypolyethoxyethanol (e.g., TRITON X-100 available from Dow Chemical Company of Midland, Michigan), trimethylnonylpolyethylene glycol (e.g., TERGITOL TMN-10 or TERGITOL 15-S-9 available from Dow Chemical Company of Midland, Mich.), or a combination thereof. Thus, in some embodiments, the chemical solution includes (e.g., comprises) at least one quaternary ammonium hydroxide, a surfactant, and water.

In some embodiments, the chemical solutions also include a corrosion inhibitor. The corrosion inhibitor may include diethylenetriamine (DETA), n-methyl-2-pyrrolidone (NMP), or a combination thereof. Thus, in some embodiments, the chemical solution includes (e.g., comprises) at least one quaternary ammonium hydroxide, a surfactant, a corrosion inhibitor, and water.

In some embodiments, the photomask 100 is exposed to the chemical solution by, for example, spraying the chemical solution onto the photomask 100, submerging the photomask 100 in the chemical solution (e.g., a bath treatment), or a combination thereof. Before, during, and/or after the exposure to the chemical solution, mechanical processes (e.g., brushing) and/or ultrasonic energy may also be applied to facilitate the removal of the carbon residue. In some embodiments, the photomask 100 is exposed to the chemical solution with the chemical solution at room temperature (e.g., about 21° C.), while in some embodiments, the chemical solution is heated to about 80° C.

In some embodiments, the chemical solution includes not more than about 20 mass % of the quaternary ammonium hydroxide (e.g., TEAH and/or TPAH), preferably not more than about 15 mass % of the quaternary ammonium hydroxide. For example, in some embodiments, the chemical solution includes about 15 mass % TEAH or about 10 mass % TPAH.

In some embodiments, the chemical solution also includes not more than about 5 mass % of the surfactant (e.g., t-octylphenoxypolyethoxyethanol and/or trimethylnonylpolyethylene glycol), preferably not more than about 2 mass % of the surfactant. For example, in some embodiments, the chemical solutions includes about 1 mass % t-octylphenoxypolyethoxyethanol or trimethylnonylpolyethylene glycol.

In some embodiments, the chemical solution also includes not more than about 20 mass % of the corrosion inhibitor (e.g., DETA and/or NMP). For example, in some embodiments, the chemical solution includes about 20 mass % NMP. In some embodiments, the chemical solution includes not more than about 1 mass % of the corrosion inhibitor. For example, in some embodiments, the chemical solution includes about 0.1 mass % DETA.

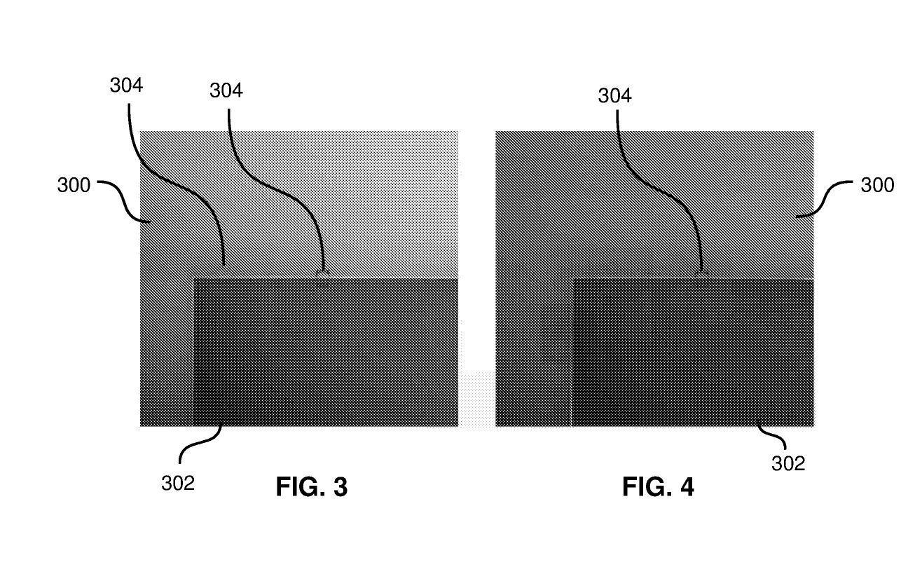

FIGS. 3-36 are scanning electron microscope (SEM) images of the results of a series of experiments demonstrating the effectiveness of various chemical solutions at cleaning carbon residue from a structure similar to the photomask 100 described above. In each of the images shown in FIGS. 3-36, the lighter region 300 corresponds to a surface made of tantalum nitride, the darker region 302 corresponds to a surface made of ruthenium, and reference numeral 304 indicates carbon residue deposited using, for example, electron beam acceleration. It should be noted that multiple deposits of carbon residue were formed on the samples before exposure to the chemical solutions. However, the carbon residue deposits were varied with respect to thickness and/or density. As a result, the “darkness” of the carbon residue deposits as seen in the images (both before and after exposure to the chemical solutions) varies significantly. On each of the sheets of figures, for the pair of images shown, the image on the left (e.g., FIG. 3) shows sample before being exposed to the respective chemical solution, and the image on the right (e.g., FIG. 4) shows the sample after being exposed to the respective chemical solution.

The chemical solution used in experiment depicted in FIGS. 3 and 4 consisted of 15 mass % TEAH, with the remainder of the solution being water (i.e., deionized water), at about room temperature (i.e., about 21° C.).

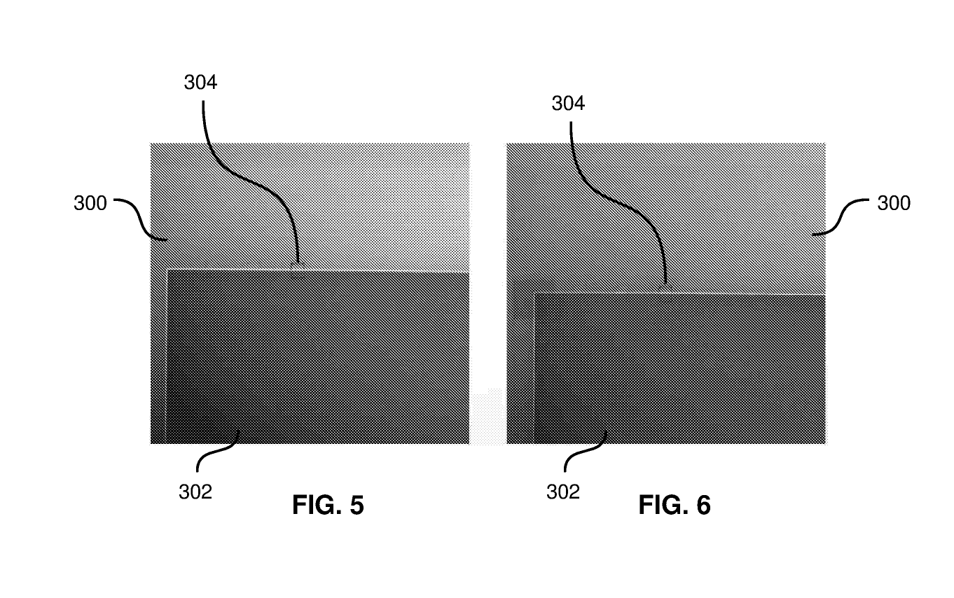

The chemical solution used in the experiment depicted in FIGS. 5 and 6 consisted of 10 mass % TPAH, with the remainder being water, at about room temperature.

It should be noted that from the images shown in FIGS. 3-6, with the chemical solution at room temperature, the chemical solutions including a quaternary ammonium hydroxide, and no surfactant or corrosion inhibitor, partially removed the lightest/faintest carbon residue deposits.

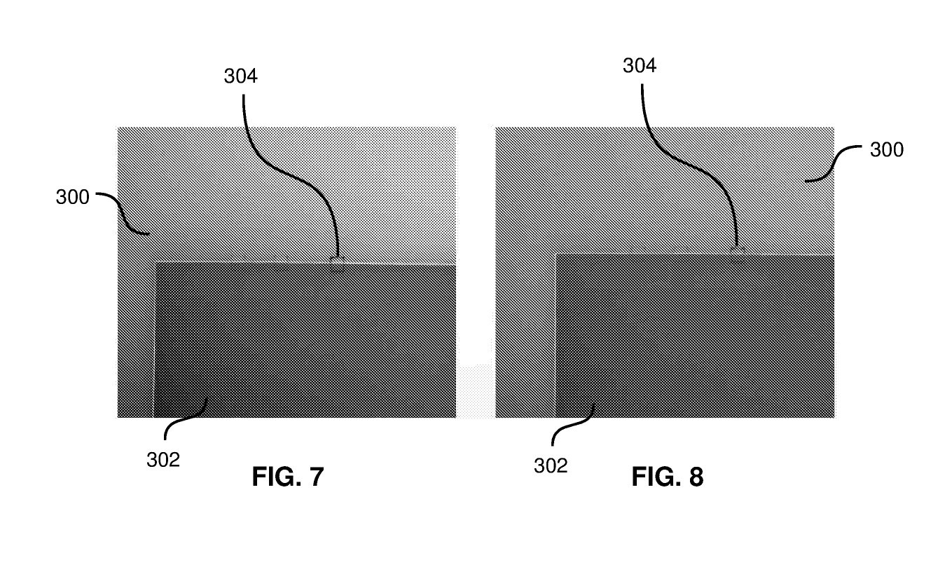

The chemical solution used in the experiment depicted in FIGS. 7 and 8 consisted of 15 mass % TEAH, 1 mass % t-octylphenoxypolyethoxyethanol, 0.1 mass % DETA, and 20 mass % NMP, with the remainder being water, at about room temperature.

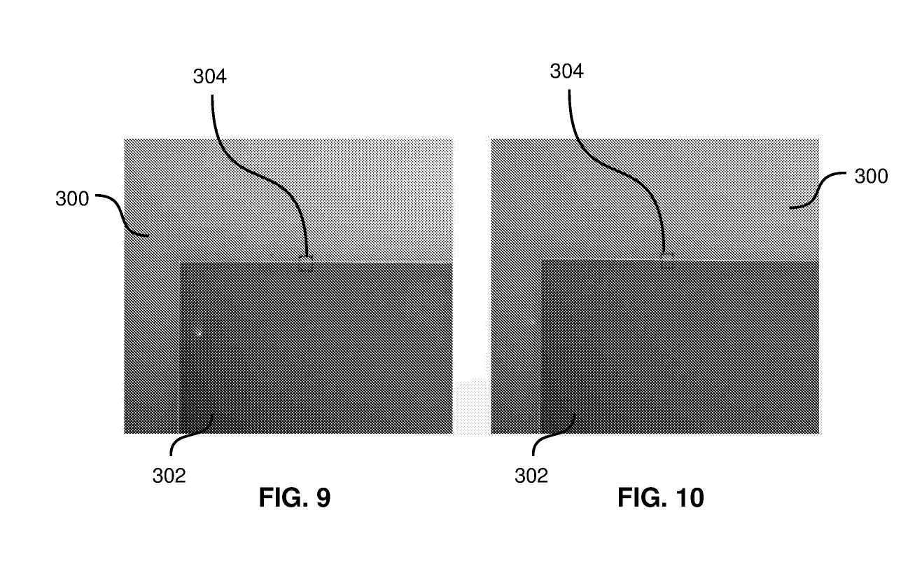

The chemical solution used in the experiment depicted in FIGS. 9 and 10 consisted of 15 mass % TEAH, 1 mass % t-octylphenoxypolyethoxyethanol, and 0.1 mass % DETA, with the remainder being water, at about room temperature.

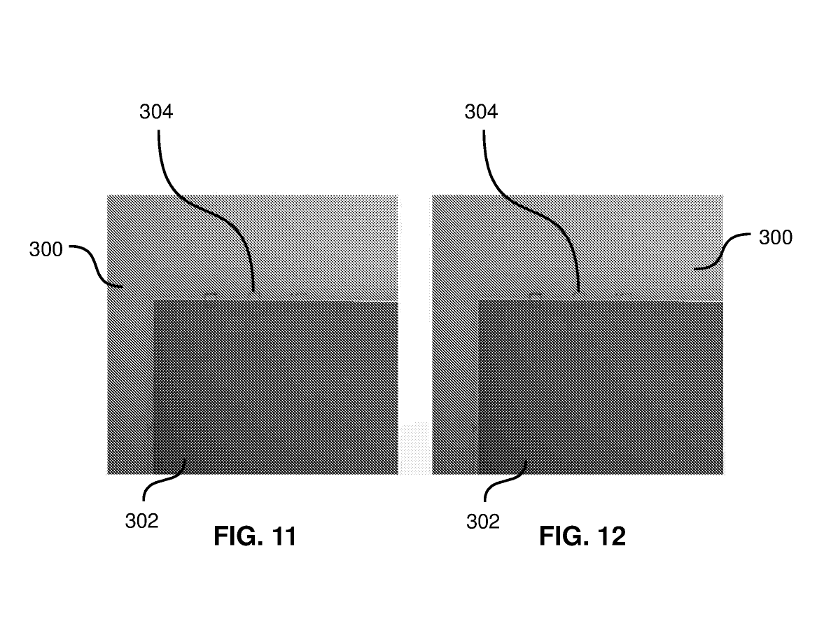

The chemical solution used in the experiment depicted in FIGS. 11 and 12 consisted of 15 mass % TEAH, 1 mass % trimethylnonylpolyethylene glycol, and 0.1 mass % DETA, with the remainder being water, at about room temperature.

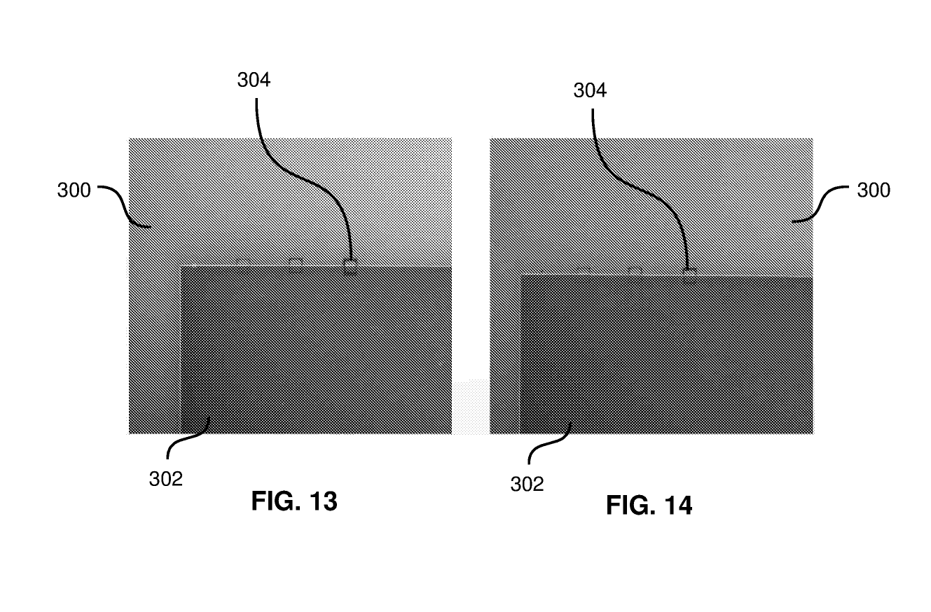

The chemical solution used in the experiment depicted in FIGS. 13 and 14 consisted of 10 mass % TPAH, 1 mass % t-octylphenoxypolyethoxyethanol, 0.1 mass % DETA, and 20 mass % NMP, with the remainder being water, at about room temperature.

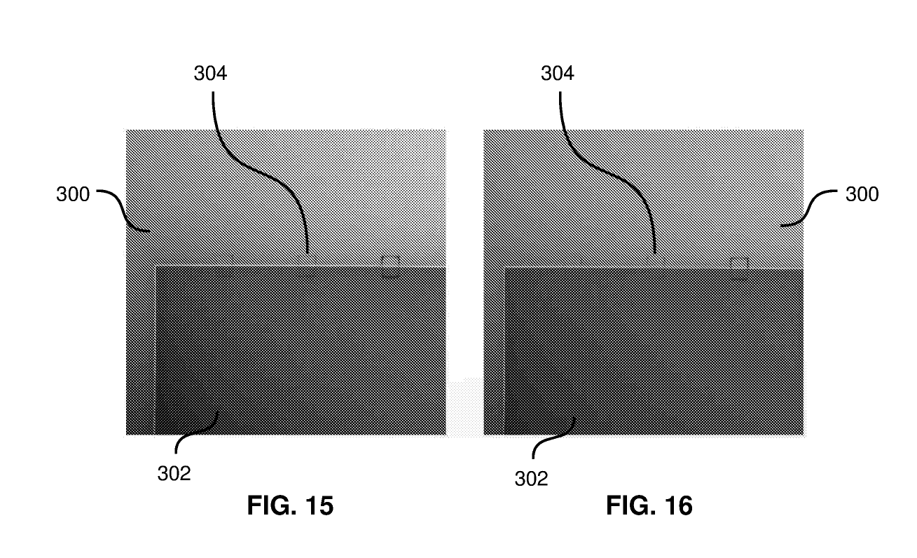

The chemical solution used in the experiment depicted in FIGS. 15 and 16 consisted of 10 mass % TPAH, 1 mass % t-octylphenoxypolyethoxyethanol, and 0.1 mass % DETA, with the remainder being water, at about room temperature.

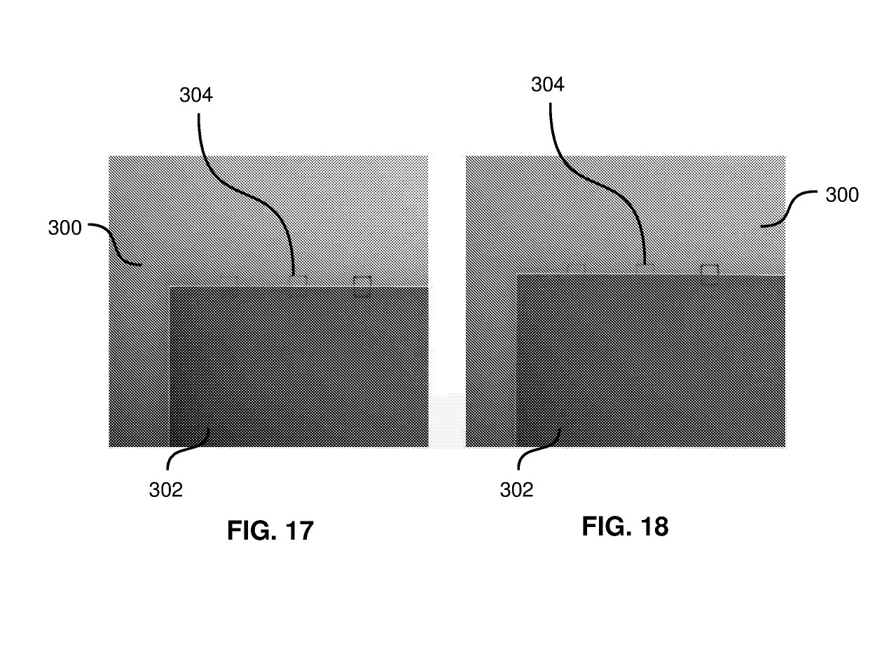

The chemical solution used in the experiment depicted in FIGS. 17 and 18 consisted of 10 mass % TPAH, 1 mass % trimethylnonylpolyethylene glycol, and 0.1 mass % DETA, with the remainder being water, at about room temperature.

It should be noted that from the images shown in FIGS. 7-18, with the chemical solution at room temperature, the chemical solutions including a quaternary ammonium hydroxide, surfactant, and corrosion inhibitor partially removed all of the carbon residue deposits.

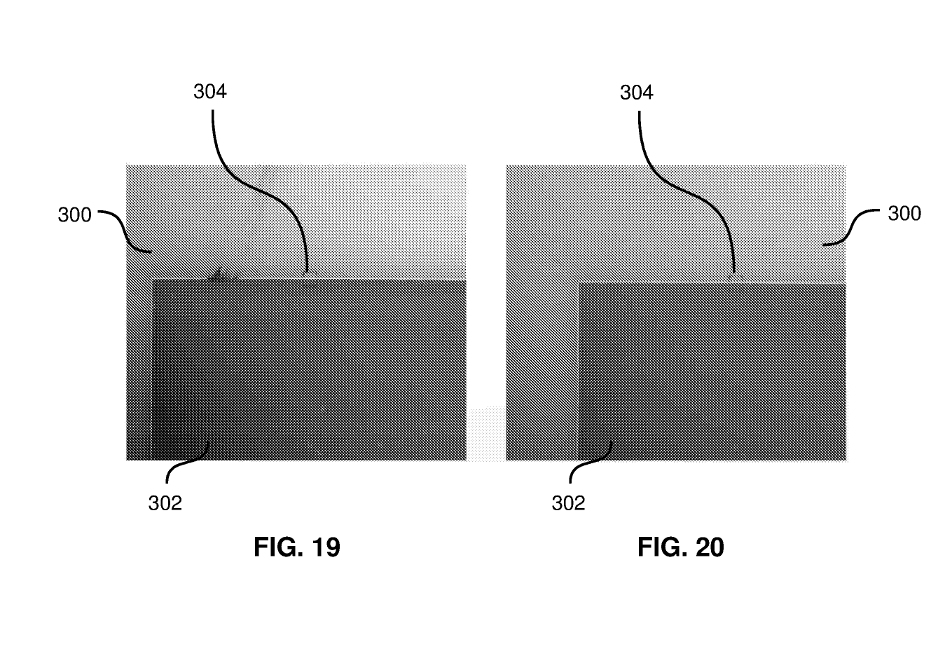

The chemical solution used in experiment depicted in FIGS. 19 and 20 consisted of 15 mass % TEAH, with the remainder of the solution being water (i.e., deionized water), at about 80° C.

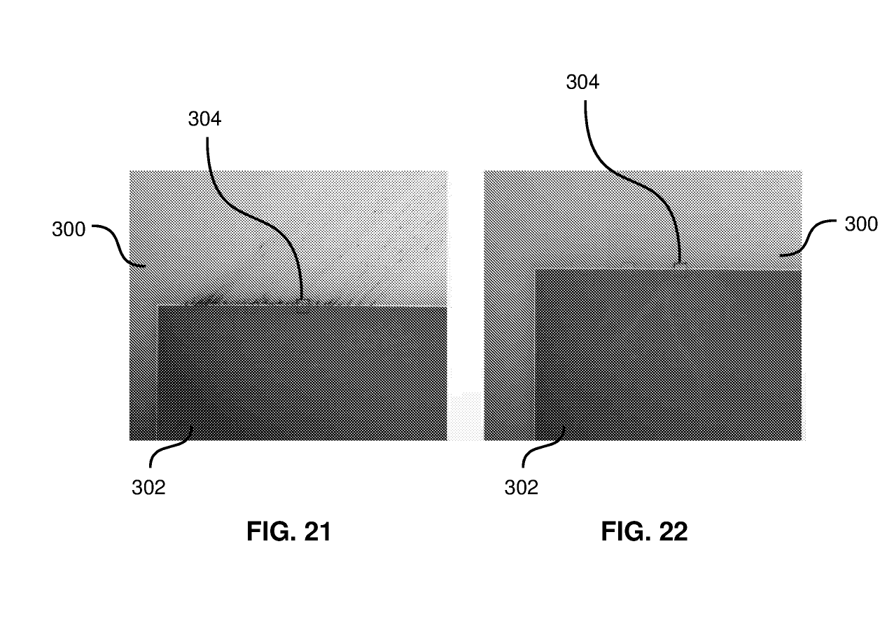

The chemical solution used in the experiment depicted in FIGS. 21 and 22 consisted of 10 mass % TPAH, with the remainder being water, at about 80° C.

It should be noted that from the images shown in FIGS. 19-22, with the chemical solution at 80° C., the chemical solutions including a quaternary ammonium hydroxide, and no surfactant or corrosion inhibitor, nearly completely removed the lightest/faintest carbon residue deposits from the ruthenium on the samples and partially removed the lightest/faintest carbon residue deposits from the tantalum nitride. It should also be noted that the chemical solutions including TEAH were slightly more effective than those including TPAH.

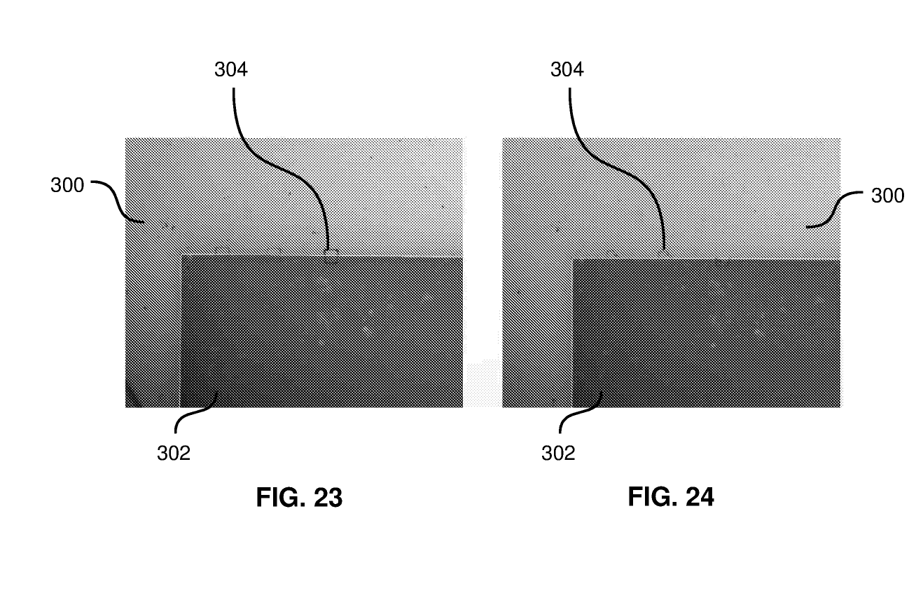

The chemical solution used in the experiment depicted in FIGS. 23 and 24 consisted of 15 mass % TEAH, 1 mass % t-octylphenoxypolyethoxyethanol, 0.1 mass % DETA, and 20 mass % NMP, with the remainder being water, at about 80° C.

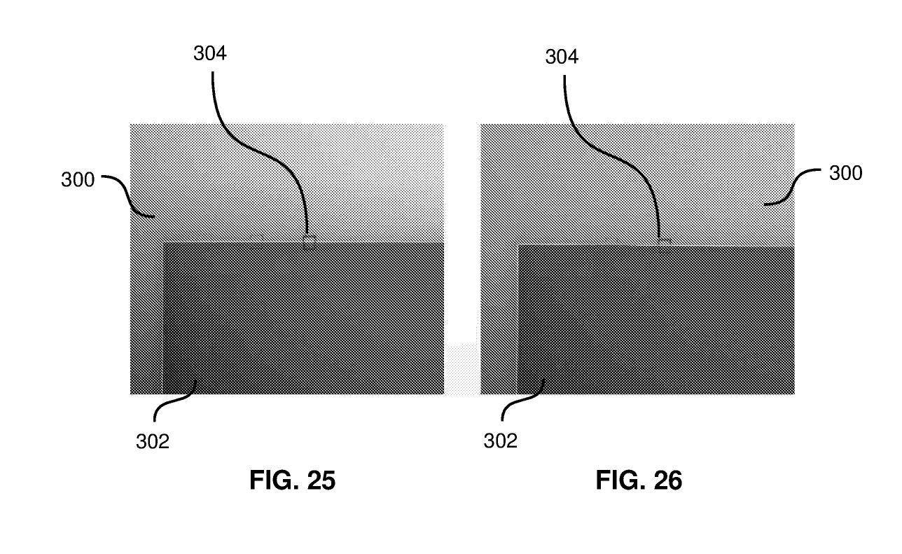

The chemical solution used in the experiment depicted in FIGS. 25 and 26 consisted of 15 mass % TEAH, 1 mass % t-octylphenoxypolyethoxyethanol, and 0.1 mass % DETA, with the remainder being water, at about 80° C. It should be noted that this particular chemical solution removed most of, if not all of, the lightest/faintest carbon residue deposit on the sample shown in FIG. 25.

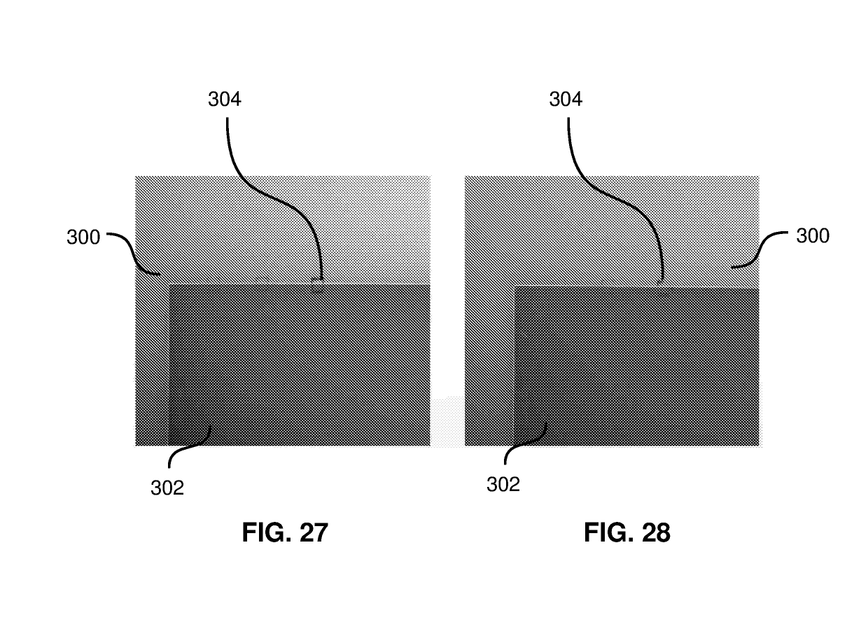

The chemical solution used in the experiment depicted in FIGS. 27 and 28 consisted of 15 mass % TEAH, 1 mass % trimethylnonylpolyethylene glycol, and 0.1 mass % DETA, with the remainder being water, at about 80° C.

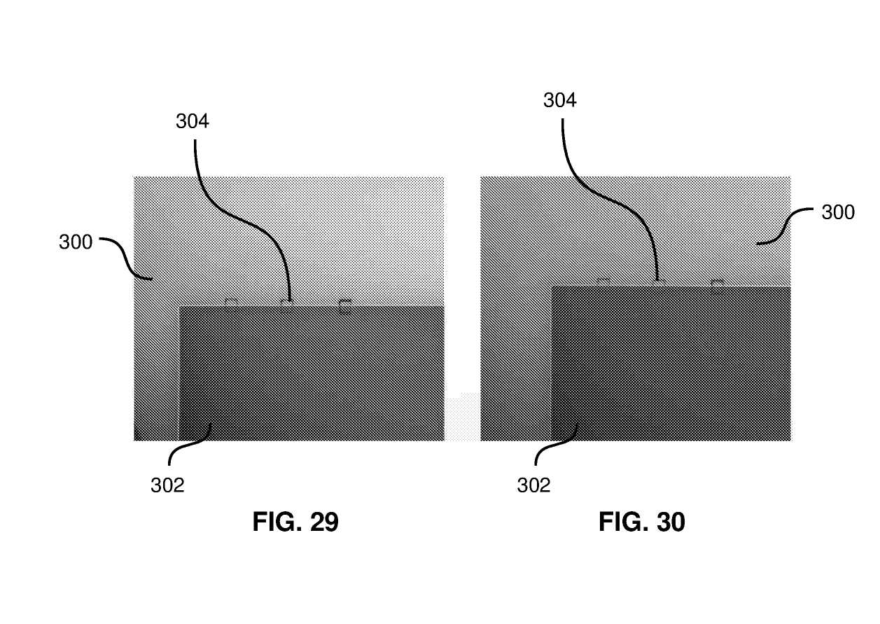

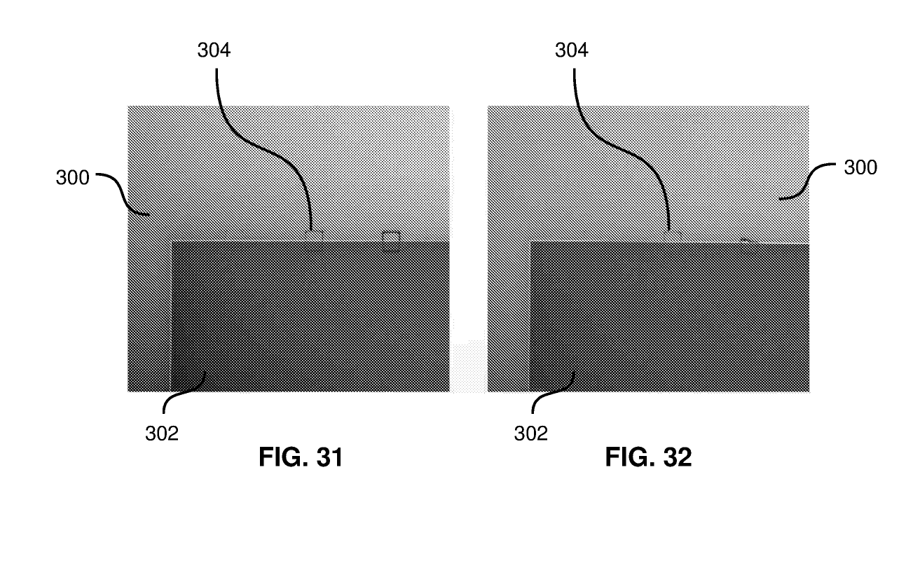

The chemical solution used in the experiment depicted in FIGS. 29 and 30 consisted of 10 mass % TPAH, 1 mass % t-octylphenoxypolyethoxyethanol, 0.1 mass % DETA, and 20 mass % NMP, with the remainder being water, at about 80° C.

The chemical solution used in the experiment depicted in FIGS. 31 and 32 consisted of 10 mass % TPAH, 1 mass % t-octylphenoxypolyethoxyethanol, and 0.1 mass % DETA, with the remainder being water, at about 80° C.

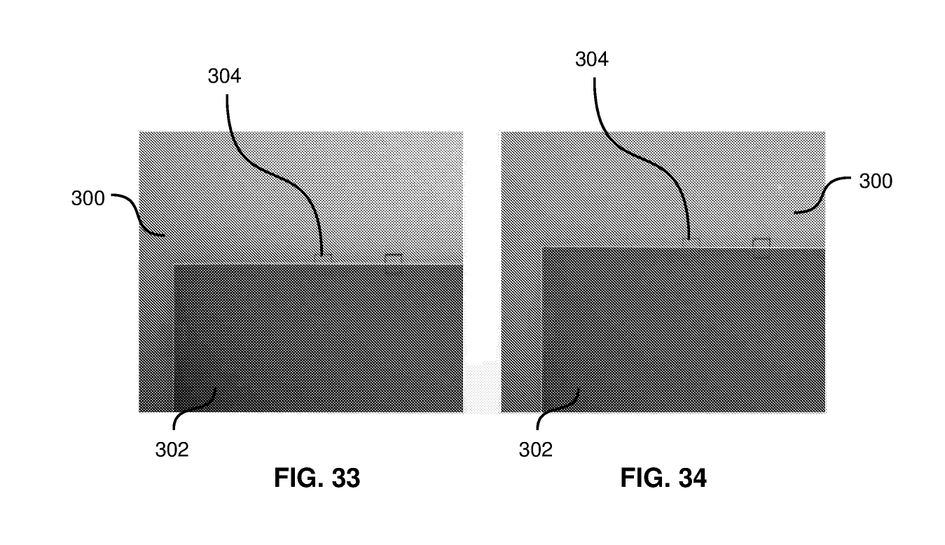

The chemical solution used in the experiment depicted in FIGS. 33 and 34 consisted of 10 mass % TPAH, 1 mass % trimethylnonylpolyethylene glycol, and 0.1 mass % DETA, with the remainder being water, at about 80° C.

It should be noted that from the images shown in FIGS. 23-34, with the chemical solution at 80° C., the chemical solutions including a quaternary ammonium hydroxide, surfactant, and corrosion inhibitor, nearly completely removed the lightest/faintest carbon residue deposits from the ruthenium on the samples and showed improved removal of the darker carbon residue deposits from both the ruthenium and the tantalum nitride. It should also be noted that the chemical solutions including TEAH were slightly more effective than those including TPAH.

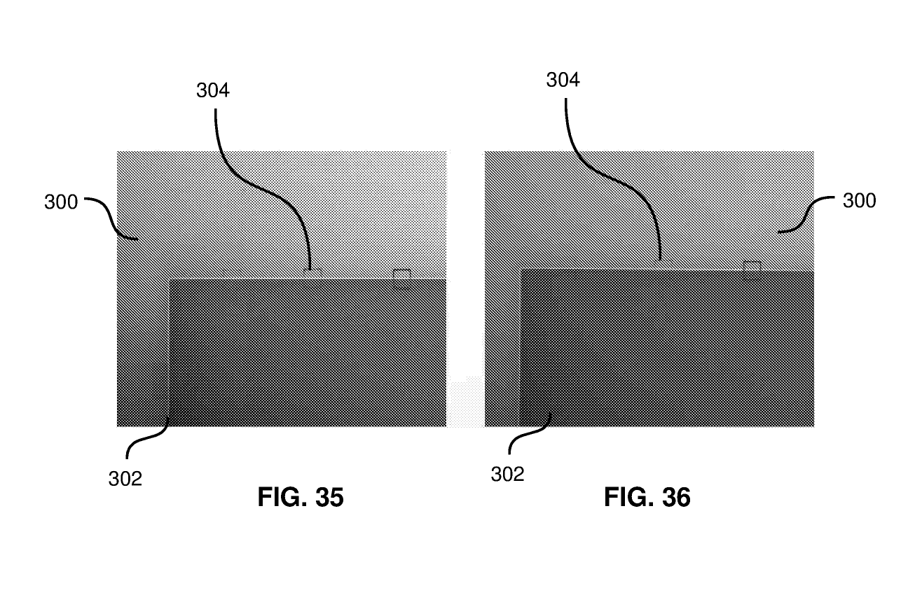

The chemical solution used in the experiment depicted in FIGS. 35 and 36 consisted of a SMP-type chemistry at about 80° C. As is shown, even the lightest/faintest carbon deposits where not completely removed.

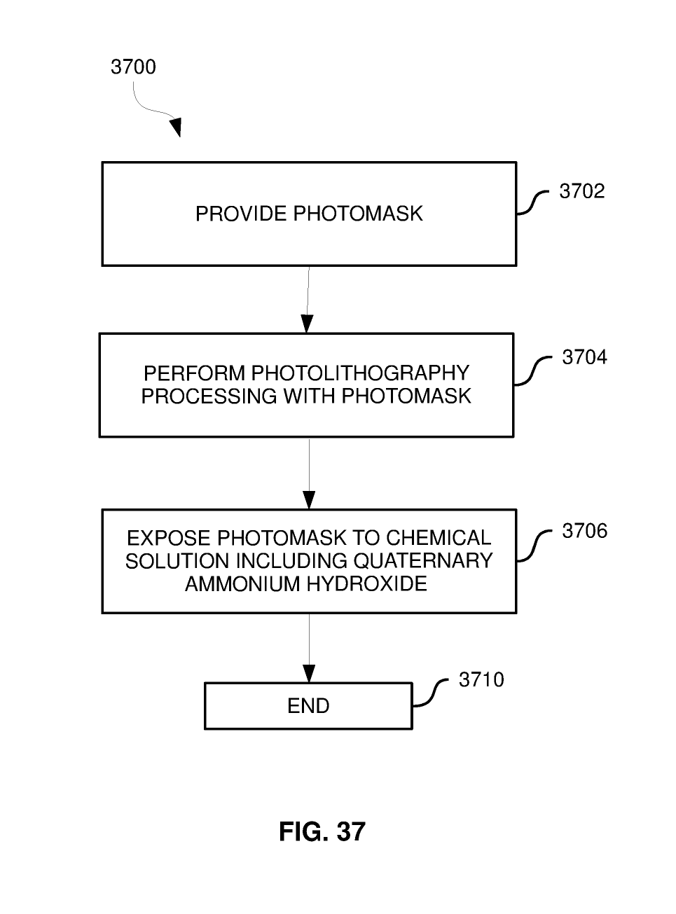

FIG. 37 illustrates a method 3700 according to some embodiments. At block 3702, a photomask is provided. The photomask may be similar to those described above. In some embodiments, the photomask includes a multi-layer stack formed above a substrate. The multi-layer stack may include a plurality of alternating first and second layers, with, for example, the first layers including molybdenum and the second layers including silicon. A capping layer that includes ruthenium may be formed above the multi-layer stack. An absorber layer that includes tantalum may be formed (and patterned) above the capping layer.

At block 3704, a photolithography process is performed using the photomask. In some embodiments, the photolithography process includes projecting electromagnetic radiation (e.g., in the ultraviolet range) onto the photomask, where it may be selectively reflected by the portions of the photomask that do not have the absorber layer formed thereon. In some embodiments, during the photolithography process, residue, such as carbon residue, is deposited or builds up on various portions of the capping layer and/or the absorber layer. It should be noted that in some embodiments, the provided photomask may have been previously used in a photolithography process and thus already have carbon residue deposited thereon. As such, block 3704 may be omitted in some embodiments.

At block 3706, the photomask is exposed to a chemical solution to at least partially remove the carbon residue. The chemical solution includes at least one quaternary ammonium hydroxide, such as TEAH, TPAH, or a combination thereof. In some embodiments, the chemical solutions also include a surfactant. The surfactant may include t-octylphenoxypolyethoxyethanol, trimethylnonylpolyethylene glycol, or a combination thereof. In some embodiments, the chemical solutions also include DETA, NMP, or a combination thereof (e.g., as a corrosion inhibitor).

At block 3710, the method ends. In some embodiments, after the photomask is exposed to the chemical solution (and/or after block 3710), the photomask is again used in one or more photolithography processes as described above.

Thus, in some embodiments, methods are provided. A photomask is provided. The photomask is exposed to a chemical solution. The chemical solution includes a quaternary ammonium hydroxide.

The photomask may be an EUV lithography photomask. The quaternary ammonium hydroxide may include at least one of TEAH, TPAH, or a combination thereof. The photomask may include ruthenium. The photomask may further include tantalum, molybdenum, and silicon.

The photomask may include a substrate. A multi-layer stack maybe formed above the substrate. The multi-layer stack may include a plurality of alternating first and second layers. The first layers may include molybdenum, and the second layers comprising silicon. A capping layer may be formed above the multi-layer stack. The capping layer may include ruthenium. An absorber layer may be formed above the capping layer. The absorber layer may include tantalum.

The chemical solution may further comprises a surfactant. The surfactant may include at least one of t-octylphenoxypolyethoxyethanol, trimethylnonylpolyethylene glycol, or a combination thereof. The chemical solution may further include at least one of DETA, NMP, or a combination thereof.

In some embodiments, methods for cleaning a photomask are provided. A photomask is provided. The photomask may include ruthenium, tantalum, molybdenum, and silicon. The photomask is exposed to a cleaning solution. The cleaning solution includes a quaternary ammonium hydroxide and a surfactant.

In some embodiments, chemical solutions for cleaning an EUV lithography photomask including comprising ruthenium are provided. The chemical solutions consist of a quaternary ammonium hydroxide, a surfactant, at least one of diethylenetriamine (DETA), n-methyl-2-pyrrolidone (NMP), or a combination thereof, and water.

Although the foregoing examples have been described in some detail for purposes of clarity of understanding, the invention is not limited to the details provided.

There are many alternative ways of implementing the invention. The disclosed examples are illustrative and not restrictive.

What is claimed:

1. A method comprising:
providing a photomask; and
exposing the photomask to a chemical solution, wherein the chemical solution comprises a quaternary ammonium hydroxide.

2. The method of claim 1, wherein the photomask is an extreme ultraviolet (EUV) lithography photomask.

3. The method of claim 2, wherein the quaternary ammonium hydroxide comprises at least one of tetraethyl ammonium hydroxide (TEAH), tetrapropyl ammonium hydroxide (TPAH), or a combination thereof.

4. The method of claim 3, wherein the photomask comprises ruthenium.

5. The method of claim 4, wherein the photomask further comprises tantalum, molybdenum, and silicon.

6. The method of claim 5, wherein the chemical solution further comprises a surfactant, wherein the surfactant comprises at least one of t-octylphenoxypolyethoxyethanol, trimethylnonylpolyethylene glycol, or a combination thereof.

7. The method of claim 6, wherein the chemical solution further comprises at least one of diethylenetriamine (DETA), n-methyl-2-pyrrolidone (NMP), or a combination thereof.

8. The method of claim 7, wherein the chemical solution comprises about 15 mass % TEAH, about 1 mass % t-octylphenoxypolyethoxyethanol, and about 0.1 mass % DETA.

9. The method of claim 8, wherein the chemical solution is heated to about 80° C. when the photomask is exposed to the chemical solution.

10. The method of claim 7, wherein the chemical solution comprises about 10 mass % TPAH, about 1 mass % t-octylphenoxypolyethoxyethanol, and about 0.1 mass % DETA.

11. A method for cleaning a photomask, the method comprising:
providing a photomask, wherein the photomask comprises ruthenium, tantalum, molybdenum, and silicon; and
exposing the photomask to a cleaning solution, wherein the cleaning solution comprises a quaternary ammonium hydroxide and a surfactant.

12. The method of claim 11, wherein the quaternary ammonium hydroxide comprises at least one of tetraethyl ammonium hydroxide (TEAH), tetrapropyl ammonium hydroxide (TPAH), or a combination thereof.

13. The method of claim 12, wherein the surfactant comprises at least one of t-octylphenoxypolyethoxyethanol, trimethylnonylpolyethylene glycol, or a combination thereof.

14. The method of claim 13, wherein the cleaning solution further comprises at least one of diethylenetriamine (DETA), n-methyl-2-pyrrolidone (NMP), or a combination thereof.

15. The method of claim 13, wherein the photomask comprises:
a substrate;
a multi-layer stack formed above the substrate, wherein the multi-layer stack comprises a plurality of alternating first and second layers, the first layers comprising molybdenum and the second layers comprising silicon;
a capping layer formed above the multi-layer stack, wherein the capping layer comprises ruthenium; and
an absorber layer formed above the capping layer, wherein the absorber layer comprises tantalum.

16. A chemical solution for cleaning an extreme ultraviolet (EUV) lithography photomask comprising ruthenium, wherein the solution comprises:
a quaternary ammonium hydroxide;
a surfactant;
at least one of diethylenetriamine (DETA), n-methyl-2-pyrrolidone (NMP), or a combination thereof; and
water.

17. The chemical solution of claim 16, wherein the chemical solutions comprises not more than about 20 mass % of the quaternary ammonium hydroxide, not more than about 5 mass % of the surfactant, and not more than about 20 mass % of the at least one of DETA, NMP, or a combination thereof.

18. The chemical solution of claim 17, wherein the quaternary ammonium hydroxide comprises at least one of tetraethyl ammonium hydroxide (TEAH), tetrapropyl ammonium hydroxide (TPAH), or a combination thereof, and the surfactant consists of at least one of t-octylphenoxypolyethoxyethanol, trimethylnonylpolyethylene glycol, or a combination thereof.

19. The chemical solution of claim 18, wherein the chemical solution comprises about 15 mass % TEAH, about 0.1 mass % t-octylphenoxypolyethoxyethanol, about 0.1 mass % DETA, and water.

20. The chemical solution of claim 18, wherein the chemical solution comprises about 7 mass % TPAH, about 0.1 mass % t-octylphenoxypolyethoxyethanol, about 0.1 mass % by DETA, and water.
